(19) United States
(12) Patent Application Publication
(10) Pub. No.: US 2009/0218581 A1
(43) Pub. Date: Sep. 3, 2009

(54) ILLUMINATION SYSTEM COMPRISING A RADIATION SOURCE AND A LUMINESCENT MATERIAL

(75) Inventors: Peter Schmidt, Aachen (DE); Thomas Juestel, Witten (DE); Walter Mayr, Alsdorf (DE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/720,845

(22) PCT Filed: Dec. 1, 2005
(86) PCT No.: PCT/IB2005/054002

§ 371 Date: Jun. 5, 2007

(30) Foreign Application Priority Data
Dec. 7, 2004 (EP) 04106355.3

(51) Int. Cl. H01L 33/00; H01J 1/62

(52) U.S. Cl. 257/98; 313/503; 257/E33.063

(57) ABSTRACT

An illumination system, comprising a radiation source (1) and a luminescent material (3,4,5) comprising at least one phosphor capable of absorbing a part of light emitted by the radiation source and emitting light of wavelength different from that of the absorbed light; wherein said at least one phosphor is a yellow red-emitting europium(II)-activated earth alkaline lithium orthosilicate of general formula (Sr1-x-y-zCaxBay)Li2SiO4:Euz wherein 0≦x≦1; 0≦y≦1; 0.001<z<0.3 can provide light sources having high luminosity and color-rendering index, especially in conjunction with a light emitting diode as a radiation source. The red to yellow-emitting europium(II)-activated earth alkaline lithium orthosilicate of general formula (Sr1-x-y-zCaxBay)Li2SiO4:Euz wherein 0<x≦1; 0≦y<1; 0.001<z<0.3 is efficiently excitable by primary radiation in the near UV-to-blue range of the electromagnetic spectrum.

### BACKGROUND OF THE INVENTION

The present invention generally relates to an illumination system comprising a radiation source and a luminescent material comprising a phosphor. The invention also relates to a phosphor for use in such illumination system.

More particularly, the invention relates to an illumination system and luminescent material comprising a phosphor for the generation of specific, colored light, including white light, by luminescent down conversion and additive color mixing based on a ultraviolet or blue radiation emitting radiation source. A light-emitting diode as a radiation source is especially contemplated.

Recently, various attempts have been made to make white light emitting illumination systems by using light emitting diodes as radiation sources. When generating white light with an arrangement of red, green and blue light emitting diodes, there has been such a problem that white light of the desired tone cannot be generated due to variations in the tone, luminance and other factors of the light emitting diodes.

In order to solve these problems, there have been previously developed various illumination systems, which convert the color of light emitting diodes by means of a luminescent material comprising a phosphor to provide a visible white light illumination.

Previous white light illumination systems have been based in particular either on the trichromatic (RGB) approach, i.e. on mixing three colors, namely red, green and blue, in which case the latter component of the output light may be provided by a phosphor or by the primary emission of the LED or in a second, simplified solution, on the dichromatic (BY) approach, mixing yellow and blue colors, in which case the yellow secondary component of the output light may be provided by a yellow phosphor and the blue component may be provided by a phosphor or by the primary emission of a blue LED.

In particular, the dichromatic approach as disclosed e.g. U.S. Pat. No. 5,998,925 uses a blue light emitting diode of InGaN based semiconductor material combined with an Y₃Al₅O₁₂:Ce (YAG-Ce³⁺) phosphor. The YAG-Ce³⁺ phosphor is coated on the InGaN LED, and a portion of the blue light emitted from the LED is converted to yellow light by the phosphor. Another portion of the blue light from the LED is transmitted through the phosphor. Thus, this system emits both blue light, emitted from the LED, and yellow light emitted from the phosphor. The mixture of blue and yellow emission bands is perceived by an observer as white light with a typical CRI in the middle 70ties and a color temperature Tc, that ranges from about 6000 K to about 8000 K.

Efficiency is a recognized problem with phosphor converted illumination systems, especially systems comprising light emitting diodes as a radiation source.

The efficiency of an illumination system using a source of primary radiation and a phosphor, which converts primary radiation in secondary radiation, is dependent on the efficiency of that radiation conversion process. The efficiency of a radiation conversion process is inter alia dependent on the difference in wavelength between the primary radiation source and the excitation wavelength of the phosphor.

To improve the efficiency of illumination systems there is a therefore general need of phosphors comprising a broad excitation spectrum in the UVA/blue region of the electromagnetic spectrum.

### BRIEF SUMMARY OF THE INVENTION

Especially, there is a need to provide illumination systems comprising new phosphors that emit in the visible yellow to red range and are excitable with high efficiency by a radiation source emitting primary radiation in a broad wavelength range of the near UV-to-blue range of the electromagnetic spectrum.

Thus the present invention provides an illumination system, comprising a radiation source and a luminescent material comprising at least one phosphor capable of absorbing a part of light emitted by the radiation source and emitting light of wavelength different from that of the absorbed light; wherein said at least one phosphor is an europium(II)-activated earth alkaline lithium orthosilicate of general formula (Sr_{1-x-y-z}CaₓBa_{y})Li₂SiO₄:Eu_{z} wherein 0≦x≦1; 0≦y≦1; 0.001≦z≦0.3.

An illumination system according to the present invention provides visible light with high efficiency as an europium(H)-activated earth alkaline lithium orthosilicate of general formula (Sr_{1-x-y-z}CaₓBa_{y})Li₂SiO₄:Eu_{z} wherein 0≦x≦1; 0≦y≦1; 0.001≦z≦0.3 provides a broad excitation band in the blue and UVA range of the electromagnetic spectrum. Such illumination system has desirable characteristics for general lighting purposes providing high brightness at economical cost.

An illumination system according to the present invention can provide a composite white output light that is well balanced with respect to color. In particular, the composite white output light has a greater amount of emission in the red color range than the conventional illumination system. This characteristic makes the device ideal for applications in which a true color rendition together with high efficiency is required.

Such applications of the invention include inter alias traffic lighting, street lighting, security lighting and lighting of automated factory, and signal lighting for cars and traffic.

Especially contemplated as a radiation source is a light emitting diode.

According to a first aspect of the invention a white light illumination system comprises a blue-light emitting diode having a peak emission wavelength in the range of 400 to 480 nm as a radiation source and a luminescent material comprising at least one phosphor, that is a europium(II)-activated earth alkaline lithium orthosilicate of general formula (Sr_{1-x-y-z}CaₓBa_{y})Li₂SiO₄:EU_{z} wherein 0≦x≦1; 0≦y≦1; 0.001≦z≦0.3.

Such illumination system will provide white light in operation. The blue light emitted by the LED excites the phosphor, causing it to emit yellow to orange light. The blue light emitted by the LED is transmitted through the phosphor and is mixed with the yellow to orange light emitted by the phosphor. The viewer perceives the mixture of blue and yellow to orange light as white light.

An essential factor is that the excitation spectrum of yellow to red phosphors of the europium(II)-activated earth alkaline lithium orthosilicate type are so broad-banded in the range from 420 to 480 nm, that they are sufficiently excited by all blue to violet light emitting diodes in the market.

According to one embodiment of the first aspect the invention provides a white light illumination system comprising a blue-light emitting diode having a peak emission wavelength in the range of 400 to 480 nm as a radiation source and a luminescent material comprising a europium(II)-activated earth alkaline lithium orthosilicate of general (Sr_{1-x-y-z}CaₓBa_{y})Li₂SiO₄:Eu_{z} wherein 0≦x≦1; 0≦y≦1; 0.001≦z≦0.3 and at least one second phosphor.

When the luminescent material comprises a phosphor blend of a phosphor of the europium(II)-activated earth alkaline lithium orthosilicate type and at least one second phosphor the color rendition of the white light illumination system according to the invention may be further improved.

In particular, the luminescent material of this embodiment may be a phosphor blend, comprising a europium(II)-activated earth alkaline lithium orthosilicate of general formula (Sr_{1-x-y-z}CaₓBa_{y})Li₂SiO₄:Eu_{z} wherein 0≦x≦1; 0≦y≦1; 0.001≦z≦0.3 and a red phosphor.

Such red phosphor may be selected from the group of Eu(II)-activated phosphors, comprising (Ca₁₋ₓSrₓ)S:Eu, wherein 0≦x≦1 and (Sr_{1-x-y}BaₓCa_{y})_{2-z}Si₅₋ₐAlₐN₈₋ₐOₐ:Eu_{z} wherein 0≦a<5, 0<x≦1, 0≦y≦1 and 0<z≦1.

Otherwise the luminescent material may be a phosphor blend, comprising europium(II)-activated earth alkaline lithium orthosilicate of general formula (Sr_{1-x-y-z}CaₓBa_{y})Li₂SiO₄:Eu_{z} wherein 0≦x≦1; 0≦y≦1; 0.001≦z≦0.3 and a yellow-to-green phosphor. Such yellow-to-green phosphor may be selected from the group comprising (Ba₁₋ₓSrₓ)₂SiO₄:Eu, wherein 0≦x≦1, SrGa₂S₄:Eu, SrSi₂N₂O₂:Eu, Ln₃Al₅O₁₂:Ce, wherein Ln comprises lanthanum and all lanthanide metals, and Y₃Al₅O₁₂:Ce.

The emission spectrum of such a luminescent material comprising additional phosphors has the appropriate wavelengths to obtain together with the blue light of the LED and the yellow to red light of the europium(II)-activated earth alkaline lithium orthosilicate type phosphor according to the invention a high quality white light with good color rendering at the required color temperature.

According to another embodiment of the invention there is provided a white light illumination system, wherein the radiation source is selected from the light emitting diodes having an emission with a peak emission wavelength in the UV-range of 200 to 400 nm and the luminescent material comprises at least one phosphor, that is a europium(II)-activated earth alkaline lithium orthosilicate of general formula (Sr_{1-x-y-z}CaₓBa_{y})Li₂SiO₄:Eu_{z} wherein 0≦x≦1; 0≦y≦1; 0.001≦z≦0.3 and a second phosphor.

In particular, the luminescent material according to this embodiment may comprise a white light emitting phosphor blend, comprising a europium(II)-activated earth alkaline lithium orthosilicate of general formula (Sr_{1-x-y-z}CaₓBa_{y})Li₂SiO₄:Eu_{z} wherein 0≦x≦1; 0≦y≦1; 0.001≦z≦0.3 and a blue phosphor.

Such blue phosphor may be selected from the group comprising BaMgAlₗₒ0₁₇:Eu, Ba₅SiO₄(Cl,Br)₆:Eu, CaLn₂S₄:Ce, wherein Ln comprises lanthanum and all lanthanide metals and (Sr,Ba,Ca)₅(PO₄)₃Cl:Eu.

A second aspect of the present invention provides an illumination system providing red to yellow light. Applications of the invention include security lighting as well as signal lighting for cars and traffic.

Especially contemplated is a yellow to red light illumination system, wherein the radiation source is selected from the blue light emitting diodes having an emission with a peak emission wavelength in the range of 400 to 480 nm a and the luminescent material comprises at least one phosphor, that is a europium(II)-activated earth alkaline lithium orthosilicate of general formula (Sr_{1-x-y-z}CaₓBa_{y})Li₂SiO₄:Eu_{z} wherein 0≦x≦1; 0≦y≦1; 0.001≦z≦0.3.

Also contemplated is a yellow to red light illumination system, wherein the radiation source is selected from the light emitting diodes having an emission with a peak emission wavelength in the UV-range of 200 to 400 nm and the luminescent material comprises at least one phosphor that is a europium(II)-activated earth alkaline lithium orthosilicate of general formula (Sr_{1-x-y-z}CaₓBa_{y})Li₂SiO₄:Eu_{z} wherein 0≦x≦1; 0≦y≦1; 0.001≦z≦0.3.

Another aspect of the present invention provides a phosphor capable of absorbing a part of light emitted by the radiation source and emitting light of wavelength different from that of the absorbed light; wherein said phosphor is a europium(II)-activated earth alkaline lithium orthosilicate of general formula (Sr_{1-x-y-z}CaₓBa_{y})Li₂SiO₄:Eu_{z} wherein 0≦x≦1; 0≦y≦1; 0.001≦z≦0.3.

The luminescent material is excitable by UV-A emission, which has such wavelengths as from 200 nm to 400 nm, but is excited with higher efficiency by blue light emitted by a blue light emitting diode having a wavelength around 400 to 480 nm. Thus the luminescent material has ideal characteristics for conversion of blue light of nitride semiconductor light emitting component into white light.

These europium(II)-activated earth alkaline lithium orthosilicate phosphors emit secondary radiation in a broad band in the red to yellow spectral range of the visible spectrum, when excited by primary radiation. The visible emission is so broad that there is no 80 nm wavelength range where the visible emission is predominantly located.

The radiation conversion occurs with very high efficiency, as the excitation spectrum of the phosphors according to the invention comprises a broad band in the UVA/blue region of the electromagnetic spectrum. Total conversion efficiency can be up to 90%.

Additional important characteristics of the phosphors include 1) resistance to thermal quenching of luminescence at typical device operating temperatures (e.g. 80° C.); 2) lack of interfering reactivity with the encapsulating resins used in the device fabrication and moisture; 3) suitable absorptive profiles to minimize dead absorption within the visible spectrum; 4) a temporally stable luminous output over the operating lifetime of the device and; 5) compositionally controlled tuning of the phosphors excitation and emission properties.

These europium(II)-activated earth alkaline lithium orthosilicate type phosphors may also include other cations including mixtures of cations as co-activators.

In particular, the invention relates to specific phosphor composition Sr_{1-z}Li₂SiO₄:Eu_{z} wherein 0.01≦z≦0.3, which exhibit a high quantum efficiency of 80-90%, high absorbance in the range from 250 nm to 500 nm of 60-80%, an emission spectrum with a peak wavelength of about 590 to 600 nm and low loss, below 10% of the luminescent lumen output due to thermal quenching from room temperature to 100° C.

Specific phosphor composition Sr_{1-z}Li₂SiO₄:Eu_{z}, wherein 0.01≦z≦0.3 is especially valuable as phosphor in white light emitting phosphor converted LEDs with low color temperature and improved color rendering.

These phosphors may have a coating selected from the group of fluorides and orthophosphates of the elements aluminum, scandium, yttrium, lanthanum gadolinium and lutetium, the oxides of aluminum, yttrium and lanthanum and the nitride of aluminum.

### DETAILED DESCRIPTION OF THE INVENTION

The present invention focuses on a europium(II)-activated earth alkaline lithium orthosilicate as a phosphor in any configuration of an illumination system containing a radiation source, including, but not limited to discharge lamps, luminescent lamps, LEDs, LDs and X-ray tubes. As used herein, the term “radiation” encompasses preferably radiation in the UV and visible regions of the electromagnetic spectrum.

While the use of the present phosphor is contemplated for a wide array of illumination, the present invention is described with particular reference to and finds particular application to light emitting diodes, especially UV- and blue-light-emitting diodes.

The luminescent material according to the invention comprises as a europium(II)-activated earth alkaline lithium orthosilicate. The phosphor conforms to the general formula (Sr_{1-x-y-z}CaₓBa_{y})Li₂SiO₄:EU_{z} wherein 0≦x≦1; 0≦y≦1; 0.001≦z≦0.3. This class of phosphor material is based an activated luminescence of a substituted earth alkaline lithium orthosilicate.

The phosphor of general (Sr_{1-x-y-z}CaₓBa_{y})Li₂SiO₄:EU_{z} wherein 0≦x≦1; 0≦y≦1; 0.001≦z≦0.3 comprises a host lattice SrLi₂SiO₄. The crystal structure of the host lattice is of trigonal symmetry, crystal symmetry space group being P3(1)21, wherein the axes of the unit cell are a=5.0259 and c=12.470. The activator europium(II) replaces part of the earth alkaline cations in the lattice sites of the host lattice. On these lattice sites the activator is exposed to an extremely strong ligand splitting field.

The host lattice for those materials may be five element (two cations) earth alkaline lithium orthosilicate such as europium(II)-activated strontium lithium orthosilicate Sr_{1-z}Li₂SiO₄:Eu_{z}, for example, or may comprise more that five elements such as europium(II)-activated strontium barium lithium orthosilicate (Sr_{1-y-z}Ba_{y})Li₂SiO₄:Eu_{z} for example.

The proportion z of europium(II) is preferably in a range of 0.001<z<0.09.

When the proportion z of europium(II) is 0.001 or lower, luminance decreases because the number of excited emission centers of photoluminescence due to europium(II)-cations decreases and, when the z is greater than 0.09, density quenching occurs. Density quenching refers to the decrease in emission intensity, which occurs when the concentration of an activation agent added to increase the luminance of the luminescent material is increased beyond an optimum level.

These europium(II)-activated earth alkaline lithium orthosilicate phosphors are responsive to broad energetic portions of the electromagnetic spectrum within the UV- and visible portion of the spectrum.

In particular, the phosphors according to the invention are especially excitable by a radiation source providing UV-emission with such wavelengths as 200 to 420 nm, such as an UV-LED, but is excited with higher efficiency by a radiation source providing blue having a wavelength from 400 to 480 nm, such as an blue-emitting LED. Thus the luminescent material has ideal characteristics for converting blue light of nitride semiconductor light emitting diodes into white light.

The method for producing an europium(II)-activated earth alkaline lithium orthosilicate phosphor of the present invention is not particularly restricted, and it can be produced by firing a mixture of starting materials, which provides an europium(II)-activated earth alkaline lithium orthosilicate luminescent material.

For example, one of the preferable phosphor compound represented by Sr_{1-z}Li₂SiO₄:Eu_{z} is produced by the method, where europium(III)-nitrate, earth alkaline nitrate and silicon nitride as the starting materials are weighed and compounded to give a molar ratio according to general formula Sr_{1-z}Li₂SiO₄:Eu 2%/oand then be fired.

Starting materials having a high purity of 99.9% or more and in the form of fine particle having an average particle size of 1 μm or less can be preferably used.

In the first place, the staring materials (i.e., alkaline earth carbonates, europium compounds such as the oxide, and a silicon-nitrogen compound such as silicon diimide or silicon nitride) are well mixed by a dry and/or wet process utilizing any of various known mixing method such as ball mills, V-shaped mixers, stirrers and the like.

Another preparation uses co-precipitated carbonates as the starting material. According to a specific embodiment to prepare a Sr_{1-z}Li₂SiO₄:Eu_{z}-phosphor Sr(NO₃)₂ and Eu(NO₃)₃.6H₂O are dissolved in distilled H₂O and concentrated (NH₄)₂S solution are added. After 12 hrs the solution (solution A) is filtered through a millipore filter.

Oxalic acid, H₂C₂O₄.2H₂O, is dissolved in distilled H₂O and a concentrated solution of ammonia is added until pH is slightly higher then 7. After 12 hrs the solution (solution B) is filtered through a millipore filter.

Solution A is poured in solution B while stirring. The precipitate is washed with distilled water and methanol and dried. Then, the powder is fired for 30 min at 500° C. in air.

The resulting carbonate is mixed with Li₂CO₃ and nanocrystalline silica powder (Degussa) by a wet slurry process in isopropanol and dried.

The obtained mixture is placed in a heat-resistance container such as an alumina crucible and a tungsten boat, and then fired in an electric furnace. A preferred temperature for the firing ranges from 700 to 900 degree C.

The firing atmosphere is not particularly restricted, and for example, it is preferable to conduct firing in a reducing atmosphere such as an atmosphere comprising inert gas such as nitrogen and argon and the like, and hydrogen in a proportion of 0.1 to 10 volume %. The firing period is determined upon various conditions such as the amount of the mixture charged in the container, the firing temperature and the temperature at which the product is taken out of the furnace, but generally in the range of 20 to 24 hours.

Luminescent material obtained by the above-mentioned method may be ground by using, for example, a ball mill, jet mill and the like. Moreover, washing and classification may be conducted. For enhancing the crystallinity of the resulting granular phosphor re-firing is suggested.

The resulting luminescent material is then ground, washed with water and ethanol, dried and sieved. A yellow powder is obtained, which efficiently luminescence at 590 nm under UV and blue excitation. The color point is at x=0.496 and y=0.483. The lumen equivalent is 330 lm/W.

After firing, the powders were characterized by powder X-ray diffraction (Cu, Kα-line), which showed that all compounds had formed.

Each phosphor of the europium(II)-activated earth alkaline lithium orthosilicate type emits a yellow to red fluorescence when excited by radiation of the UVA or blue range of the electromagnetic spectrum.

In FIG. 2 of the drawings accompanying this specification, the excitation, emission and reflection spectra of Sr_{1-z}Li₂SiO₄:Eu_{z} are given.

From the excitation spectra, it is obvious that these europium(II)-activated earth alkaline lithium orthosilicate phosphors can be excited efficiently with UV-radiation of wavelength of 200 to 400 nm, especially 250 nm to 350, as well as blue radiation with a wavelength 400 to 480.

When excited with radiation of wavelength 460 nm, europium(II)-activated earth alkaline lithium orthosilicate phosphors are found to give a broadband emission, which peak wavelength at 590 nm and a tail emission up to 700 nm.

Specific phosphor Sr_{1-z}Li₂SiO₄:Eu_{z} is, because of its earth alkaline lithium orthosilicate host lattice, resistant to heat, light and moisture, and is capable of absorbing excitation light having a peak at a wavelength near 430 nm as shown in FIG. 2. It also emits light of broad spectrum having a peak near 593 nm.

Preferably the europium(II)-activated earth alkaline lithium orthosilicate type phosphors according to the invention may be coated with a thin, uniform protective layer of one or more compounds selected from the group formed by the fluorides and orthophosphates of the elements aluminum, scandium, yttrium, lanthanum gadolinium and lutetium, the oxides of aluminum, yttrium and lanthanum and the nitride of aluminum.

The protective layer thickness customarily ranges from 0.001 to 0.2 μm and, thus, is so thin that it can be penetrated by the radiation of the radiation source without substantial loss of energy. The coatings of these materials on the phosphor particles can be applied, for example, by deposition from the gas phase a wet-coating process.

The invention also concerns an illumination system comprising a radiation source and a luminescent material comprising at least one europium(II)-activated earth alkaline lithium orthosilicate of general formula (Sr_{1-x-y-z}CaₓBa_{y})Li₂SiO₄:Eu_{z} wherein 0≦x≦1; 0≦y≦1; 0.001≦z≦0.3.

Radiation sources include semiconductor optical radiation emitters and other devices that emit optical radiation in response to electrical excitation. Semiconductor optical radiation emitters include light emitting diode LED chips, light emitting polymers (LEPs), organic light emitting devices (OLEDs), polymer light emitting devices (PLEDs), etc.

Moreover, light emitting components such as those found in discharge lamps and luminescent lamps, such as mercury low and high pressure discharge lamps, sulfur discharge lamps, and discharge lamps based an molecular radiators are also contemplated for use as radiation sources with the present inventive phosphor compositions.

In a preferred embodiment of the invention the radiation source is a light-emitting diode (LED).

Any configuration of an illumination system which includes a light emitting diode and a europium(II) activated earth alkaline lithium orthosilicate phosphor composition is contemplated in the present invention, preferably with addition of other well-known phosphors, which can be combined to achieve a specific color or white light when irradiated by a LED emitting primary UV or blue light as specified above.

A detailed construction of one embodiment of such illumination system comprising a radiation source and a luminescent material shown in FIG. 1 will now be described.

FIG. 1 shows a schematic view of a chip type light emitting diode with a coating comprising the luminescent material. The device comprises chip type light emitting diode (LED) 1 as a radiation source. The light-emitting diode dice is positioned in a reflector cup lead frame 2. The dice 1 is connected via a bond wire 7 to a first terminal 6, and directly to a second electric terminal 6. The recess of the reflector cup is filled with a coating material that contains a luminescent material according to the invention to form a coating layer that is embedded in the reflector cup. The phosphors 4,5, are applied either separately or in a mixture.

The coating material typically comprises a polymer 3 for encapsulating the phosphor or phosphor blend. In this embodiment, the phosphor or phosphor blend should exhibit high stability properties against the encapsulant. Preferably, the polymer is optically clear to prevent significant light scattering. A variety of polymers are known in the LED industry for making LED illumination systems.

In one embodiment, the polymer is selected from the group consisting of epoxy and silicone resins. Adding the phosphor mixture to a liquid that is a polymer precursor can perform encapsulation. For example, the phosphor mixture can be a granular powder. Introducing phosphor particles into polymer precursor liquid results in formation of a slurry (i.e. a suspension of particles). Upon polymerization, the phosphor mixture is fixed rigidly in place by the encapsulation. In one embodiment, both the luminescent material and the LED dice are encapsulated in the polymer.

The transparent coating material may comprise light-diffusing particles, advantageously so-called diffusers. Examples of such diffusers are mineral fillers, in particular CaF₂, TiO₂, SiO₂, CaCO₃ or BaSO₄ or any else organic pigments. These materials can be added in a simple manner to the above-mentioned resins.

In operation, electrical power is supplied to the dice to activate the dice. When activated, the dice emits the primary light, e.g. blue light. A portion of the emitted primary light is completely or partially absorbed by the luminescent material in the coating layer. The luminescent material then emits secondary light, i.e., the converted light having a longer peak wavelength, primarily yellow in a sufficiently broadband (specifically with a significant proportion of red) in response to absorption of the primary light. The remaining unabsorbed portion of the emitted primary light is transmitted through the luminescent layer, along with the secondary light. The encapsulation directs the unabsorbed primary light and the secondary light in a general direction as output light. Thus, the output light is a composite light that is composed of the primary light emitted from the die and the secondary light emitted from the luminescent layer.

The color temperature or color point of the output light of an illumination system according to the invention will vary depending upon the spectral distributions and intensities of the secondary light in comparison to the primary light.

Firstly, the color temperature or color point of the primary light can be varied by a suitable choice of the light emitting diode.

Secondly, the color temperature or color point of the secondary light can be varied by a suitable choice of the phosphor in the luminescent material, its particle size and its concentration. Furthermore, these arrangements also advantageously afford the possibility of using phosphor blends in the luminescent material, as a result of which, advantageously, the desired hue can be set even more accurately.

According to one aspect of the invention the output light of the illumination system may have a spectral distribution such that it appears to be “white” light.

In a first embodiment, a white-light emitting illumination system according to the invention can advantageously be produced by choosing the luminescent material such that a blue radiation emitted by a blue light emitting diode is converted into complementary wavelength ranges, to form dichromatic white light.

In this case, yellow light is produced by means of the luminescent materials that comprise a europium(II)-activated earth alkaline lithium orthosilicate phosphor. Also a second luminescent material can be used, in addition, in order to improve the color rendition of this illumination system.

Particularly good results are achieved with a blue LED whose emission maximum lies at 400 to 480 nm. An optimum has been found to lie at 445 to 468 nm, taking particular account of the excitation spectrum of the europium(II)-activated earth alkaline lithium orthosilicate.

In a specific embodiment a white-light emitting illumination system according to the invention can particularly preferably be realized by admixing the inorganic luminescent material Sr_{1-z}Li₂SiO₄:Eu_{z} with a silicon resin used to produce the luminescence conversion encapsulation or layer for a 462 nm InGaN light emitting diode.

Part of a blue radiation emitted by a 462 nm InGaN light emitting diode is shifted by the inorganic luminescent material Sr_{1-z}Li₂SiO₄:Eu_{z} into the orange spectral region and, consequently, into a wavelength range which is complementarily colored with respect to the color blue. A human observer perceives the combination of blue primary light and the secondary light of the yellow-emitting phosphor as white light.

FIGS. 3 and 4 shows the emission spectra of such illumination system comprising blue emitting InGaN die with primary emission at 462 nm and Sr_{1-z}Li₂SiO₄:Eu_{z} as the luminescent material, which together form an overall spectrum which conveys a white color sensation of high quality.

In another embodiment, a white-light emitting illumination system according to the invention can advantageously be produced by choosing the luminescent material such that a blue radiation emitted by the blue light emitting diode is converted into complementary wavelength ranges, to form polychromatic white light. In this case, yellow light is produced by means of the luminescent materials that comprise a blend of phosphors including europium(II)-activated earth alkaline lithium orthosilicate phosphor and a second phosphor.

Yielding white light emission with even high color rendering is possible by using red and green broad band emitter phosphors covering the whole spectral range together with a blue-emitting LED and a yellow to red emitting europium(II)-activated earth alkaline lithium orthosilicate phosphor.

Useful second phosphors and their optical properties are summarized in the following Table 2.

TABLE 2

| Composition | λₘₐₓ [nm] | Color point x, y |
|---|---|---|
| (Ba₁₋ₓSrₓ)₂SiO₄: Eu | 523 | 0.272, 0.640 |
| SrGa₂S₄: Eu | 535 | 0.270, 0.686 |
| SrSi₂N₂O₂: Eu | 541 | 0.356, 0.606 |
| SrS: Eu | 610 | 0.627, 0.372 |
| (Sr_{1-x-y}CaₓBa_{y})₂Si₅N₈: Eu | 615 | 0.615, 0.384 |
| (Sr_{1-x-y}CaₓBa_{y})₂Si₅₋ₐAlₐN₈₋ₐOₐ: Eu | 615-650 | * |
| CaS: Eu | 655 | 0.700, 0.303 |
| (Sr₁₋ₓCaₓ)S: Eu | 610-655 | * |

The luminescent materials may be a blend of two phosphors, a yellow to red europium(II) activated earth alkaline lithium orthosilicate phosphor and a red phosphor selected from the group (Ca₁₋ₓSrₓ)S:Eu, wherein 0≦x≦1 and (Sr_{1-x-y}BaₓCa_{y})₂Si₅₋ₐAlₐN₈₋ₐOₐ:Eu_{z} wherein 0≦a<5, 0<x≦1; 0≦y≦1 and 0≦z≦1.

The luminescent materials may be a blend two phosphors, a yellow to red europium(II) activated earth alkaline lithium orthosilicate phosphor and a green phosphor selected from the group comprising (Ba₁₋ₓSrₓ)₂SiO₄:Eu, wherein 0≦x≦1, SrGa₂S₄:Eu and SrSi₂N₂O₂:Eu.

The following table summarizes the efficiency and color rendering data of white LEDs based on luminescent material comprising a phosphor blend consisting of 5 to 40% SrGa₂S₄:Eu and 60 to 95% SrLi₂SiO₄:Eu as function of color temperature.

TABLE 1
Efficiency (Eff.) and color rendering (Ra₈) of white LEDs for various
spectral fractions x (blue emitting LED, 462 nm), y (SrGa₂S₄: Eu, SSE),
and z (SrLi₂SiO₄: Eu, SLS) as function of color temperature T_{c}

| | | | | | Eff. | Rel. Eff. |
|---|---|---|---|---|---|---|
| T_{c} [K] | x(460) | y(SSE) | z(SLS) | Ra₈ | [lm/W] | [%] |
| 4000 | 0.185 | 0.069 | 0.746 | 68 | 34.9 | 100 |
| 5000 | 0.245 | 0.108 | 0.647 | 73 | 33.9 | 97 |
| 6300 | 0.295 | 0.153 | 0.552 | 74 | 33.4 | 96 |
| 8000 | 0.351 | 0.147 | 0.502 | 77 | 31.6 | 91 |
| 8600 | 0.363 | 0.151 | 0.486 | 77 | 31.3 | 90 |

The luminescent materials for an illumination system using a blue emitting LED for providing polychromatic white light may also be a blend of three (or more) phosphors, e.g. a yellow to red europium(II) activated earth alkaline lithium orthosilicate phosphor, a red phosphor selected from the group (Ca₁₋ₓSrₓ)S:Eu, wherein 0≦x≦1 and (Sr_{1-x-y}BaₓCa_{y})₂Si₅₋ₐAlₐN₈₋ₐOₐ:Eu wherein 0≦a<5, 0<x≦1 and 0≦y≦1 and a green phosphor selected from the group comprising (Ba₁₋ₓSrₓ)₂SiO₄:Eu, wherein 0≦x≦1, SrGa₂S₄:Eu and SrSi₂N₂O₂:Eu.

A white-light emitting illumination system according to this aspect of the invention can particularly preferably be realized by admixing the inorganic luminescent material comprising a mixture of three phosphors with a silicon resin used to produce the luminescence conversion encapsulation or layer. A first phosphor (1) is the yellow-emitting earth alkaline lithium orthosilicate Sr_{1-z}Li₂SiO₄:Eu_{z}, the second phosphor (2) is the red-emitting CaS:Eu, and the third (3) is a green-emitting phosphor of type SrSi₂N₂O₂:Eu. Part of a blue radiation emitted by a 462 nm InGaN light emitting diode is shifted by the inorganic luminescent material Sr_{1-z}Li₂SiO₄:Eu_{z} into the yellow spectral region and, consequently, into a wavelength range which is complementarily colored with respect to the color blue. Another part of blue radiation emitted by a 462 nm InGaN light emitting diode is shifted by the inorganic luminescent material CaS:Eu into the red spectral region. Still another part of blue radiation emitted by a 462 nm InGaN light emitting diode is shifted by the inorganic luminescent material SrSi₂N₂O₂:Eu into the green spectral region. A human observer perceives the combination of blue primary light and the polychromatic secondary light of the phosphor blend as white light.

The hue (color point in the CIE chromaticity diagram) of the white light thereby produced can in this case be varied by a suitable choice of the phosphors in respect of mixture and concentration.

In another embodiment, a white-light emitting illumination system according to the invention can advantageously be produced by choosing the luminescent material such that a UV radiation emitted by the UV light emitting diode is converted into complementary wavelength ranges, to form dichromatic white light. In this case, the yellow and blue light is produced by means of the luminescent materials. Yellow to red light is produced by means of the luminescent materials that comprise a europium(II)-activated earth alkaline lithium orthosilicate phosphor. Blue light is produced by means of the luminescent materials that comprise a blue phosphor selected from the group comprising BaMgAlₗₒ0₁₇:Eu, Ba₅SiO₄(Cl,Br)₆:Eu, CaLn₂S₄:Ce and (Sr,Ba,Ca)₅(PO₄)₃Cl:Eu.

Particularly good results are achieved in conjunction with a UVA light emitting diode, whose emission maximum lies at 300 to 400 nm. An optimum has been found to lie at 365 nm, taking particular account of the excitation spectrum of the europium(II)-activated earth alkaline lithium orthosilicate.

In a specific embodiment, a white-light emitting illumination system according to the invention can advantageously be produced by choosing the luminescent material such that UV radiation emitted by a UV emitting diode is converted into complementary wavelength ranges, to form polychromatic white light e.g. by additive color triads, for example blue, green and red.

In this case, the yellow to red, the green and blue light is produced by means of the luminescent materials.

Also a second red luminescent material can be used, in addition, in order to improve the color rendition of this illumination system.

Yielding white light emission with especially high color rendering is possible by using blue and green broad band emitter phosphors covering the whole spectral range together with a UV emitting LED and a yellow to red emitting europium(II)-activated earth alkaline lithium orthosilicate phosphor.

The luminescent materials may be a blend of a yellow to red europium(II) activated earth alkaline lithium orthosilicate phosphor, a blue phosphor selected from the group comprising BaMgAlₗₒ0₁₇:Eu, Ba₅SiO₄(Cl,Br)₆:Eu, CaLn₂S₄:Ce and (Sr,Ba,Ca)₅(PO₄)₃Cl:Eu and a green phosphor selected from the group comprising (Ba₁₋ₓSrₓ)₂SiO₄:Eu, wherein 0≦x≦1, SrGa₂S₄:Eu and SrSi₂N₂O₂:Eu.

The hue (color point in the CIE chromaticity diagram) of the white light thereby produced can in this case be varied by a suitable choice of the phosphors in respect of mixture and concentration.

According to further aspect of the invention an illumination system that emits output light having a spectral distribution such that it appears to be “yellow to red” light is contemplated.

Luminescent material comprising europium(II) activated earth alkaline lithium orthosilicate as phosphor is particularly well suited as a yellow component for stimulation by a primary UVA or blue radiation source such as, for example, an UVA-emitting LED or blue-emitting LED.

It is possible thereby to implement an illumination system emitting in the yellow to red regions of the electromagnetic spectrum.

In an embodiment of this aspect of the invention, a yellow-light emitting illumination system can advantageously be produced by choosing the luminescent material such that a blue radiation emitted by the blue light emitting diode is converted into complementary wavelength ranges, to form dichromatic yellow light.

In this case, yellow light is produced by means of the luminescent materials that comprise a europium(II)-activated earth alkaline lithium orthosilicate phosphor.

Particularly good results are achieved with a blue LED whose emission maximum lies at 400 to 480 nm. An optimum has been found to lie at 445 to 465 nm, taking particular account of the excitation spectrum of the earth alkaline lithium orthosilicate.

A yellow-light emitting illumination system according to the invention can particularly preferably be realized by admixing an excess of the inorganic luminescent material Sr_{1-z}Li₂SiO₄:Eu_{z} with a silicon resin used to produce the luminescence conversion encapsulation or layer. Part of a blue radiation emitted by a 462 nm InGaN light emitting diode is shifted by the inorganic luminescent material Sr_{1-z}Li₂SiO₄:Eu_{z} into the yellow spectral region and, consequently, into a wavelength range which is complementarily colored with respect to the color blue. A human observer perceives the combination of blue primary light and the excess secondary light of the yellow-emitting phosphor as yellow light.

The color output of the LED—phosphor system is very sensitive to the thickness of the phosphor layer, if the phosphor layer is thick and comprises an excess of a yellow europium(II) activated earth alkaline lithium orthosilicate phosphor, then a lesser amount of the blue LED light will penetrate through the thick phosphor layer. The combined LED—phosphor system will then appear yellow to red, because it is dominated by the yellow to red secondary light of the phosphor. Therefore, the thickness of the phosphor layer is a critical variable affecting the color output of the system.

The hue (color point in the CIE chromaticity diagram) of the yellow light thereby produced can in this case be varied by a suitable choice of the phosphor in respect of mixture and concentration.

In a further embodiment of this aspect of the invention, a yellow to red-light emitting illumination system according to the invention can advantageously be produced by choosing the luminescent material such that a UV radiation emitted by the UV emitting diode is converted entirely into monochromatic yellow to red light. In this case, the yellow to red light is produced by means of the luminescent materials.

A yellow-light emitting illumination system according to the invention can particularly preferably be realized by admixing the inorganic luminescent material Sr_{1-z}Li₂SiO₄:Eu_{z} with a silicon resin used to produce the luminescence conversion encapsulation or layer. Part of a blue radiation emitted by a 462 nm InGaN light emitting diode is shifted by the inorganic luminescent material Sr_{1-z}Li₂SiO₄:Eu_{z} into the yellow spectral region. A human observer perceives the combination of UVA primary radiation and the secondary light of the yellow-emitting phosphor as yellow light.

The hue (color point in the CIE chromaticity diagram) of the white light thereby produced can in this case be varied by a suitable choice of the phosphor in respect of mixture and concentration.

### BRIEF DESCRIPTION OF THE DRAWINGS

FIG. 1 shows a schematic view of a dichromatic white LED lamp comprising a phosphor of the present invention positioned in a pathway of light emitted by an LED structure.

FIG. 2 shows excitation, emission and reflection spectra of Sr_{1-z}Li₂SiO₄:Eu_{z}

FIG. 3 shows the spectral radiance of an illumination system comprising a blue LED and Sr_{1-z}Li₂SiO₄:Eu_{z} as luminescent material with T_{c}=8000 K and CRI=77.

FIG. 4 shows the spectral radiance of an illumination system comprising a blue LED and Sr_{1-z}Li₂SiO₄:Eu_{z} as luminescent material with T_{c}=4000 K and CRI=68.

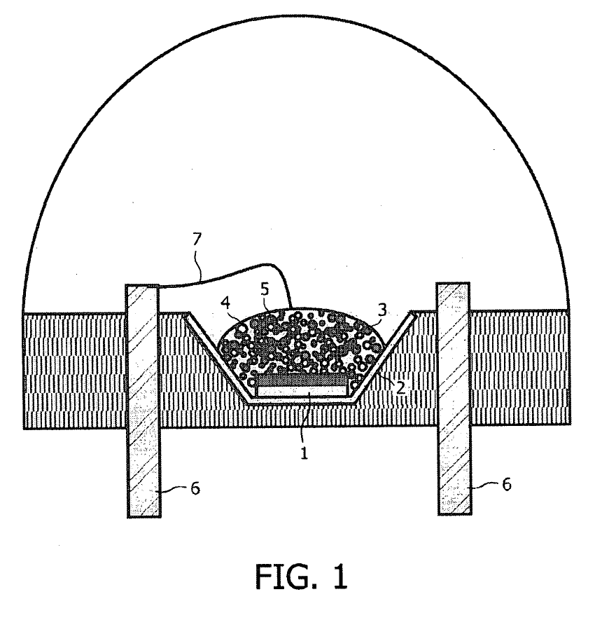

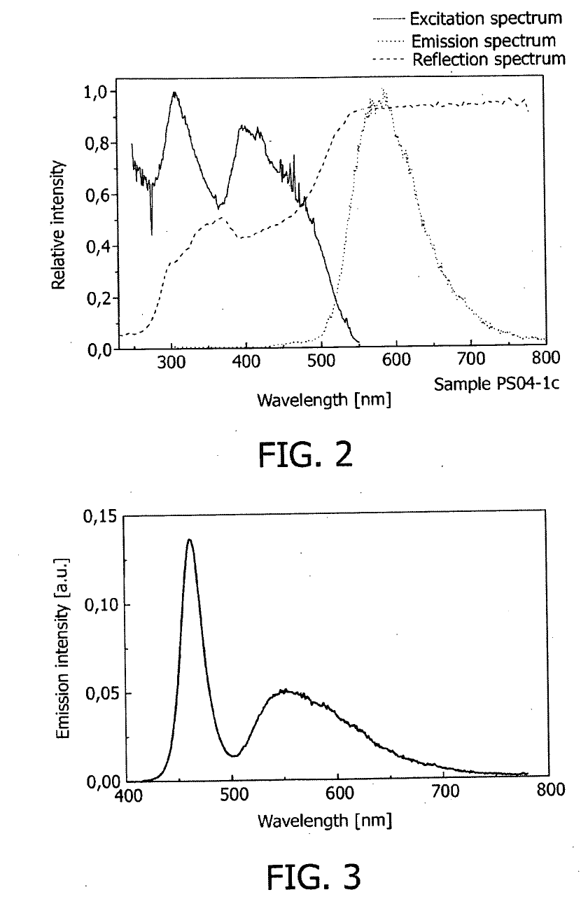

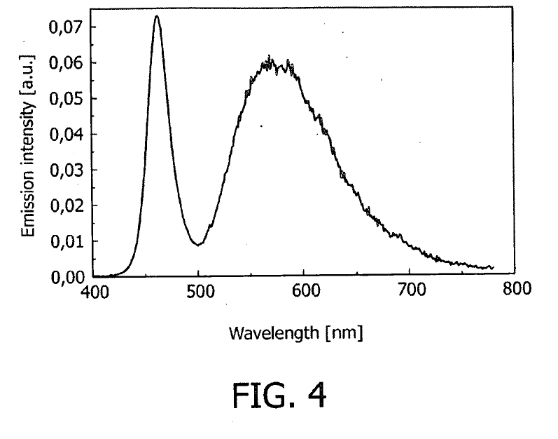

1. Illumination system, comprising a radiation source and a luminescent material comprising at least one phosphor capable of absorbing a part of light emitted by the radiation source and emitting light of a wavelength different from that of the absorbed light; wherein said at least one phosphor is an europium(II)-activated earth alkaline lithium orthosilicate of general formula (Sr_{1-x-y-z}CaₓBa_{y})Li₂SiO₄:Eu_{z} wherein 0≦x≦1; 0≦y≦1; 0.001≦z≦0.3.

2. Illumination system according to claim 1, wherein the radiation source is a light emitting diode.

3. Illumination system according to claim 1, wherein the radiation source is selected from the light emitting diodes having an emission with a peak emission wavelength in the range of 400 to 480 nm and wherein the luminescent material comprises a europium(II)-activated strontium lithium orthosilicate of general formula (Sr_{1-x-y-z}CaₓBa_{y})Li₂SiO₄:Eu_{z} wherein 0≦x≦1; 0≦y≦1; 0.001≦z≦0.3.

4. Illumination system according to claim 1, wherein the radiation source is selected from the light emitting diodes having an emission with a peak emission wavelength in the range of 400 to 480 nm and the luminescent material comprises an europium(II)-activated earth alkaline lithium orthosilicate of general formula (Sr_{1-x-y-z}CaₓBa_{y})Li₂SiO₄:Eu_{z} wherein 0≦x≦1; 0≦y≦1; 0.001≦z≦0.3 and a second phosphor.

5. Illumination system according to claim 4, wherein the second phosphor is a red phosphor selected from the group (Ca₁₋ₓSrₓ) S:Eu, wherein 0≦x≦1 and (Sr_{1-x-y}BaₓCa_{y})_{2-z}Si₅₋ₐAlₐN₈₋ₐOₐ:Eu_{z} wherein 0≦a<5; 0<x≦1, 0≦y≦1 and 0<z≦1.

6. Illumination system according to claim 4, wherein the second phosphor is a yellow to green phosphor selected from the group comprising (Ba₁₋ₓSrₓ)₂SiO₄:Eu, wherein 0≦x≦1, SrGa₂S₄:Eu, SrSi₂N₂O₂:Eu, Ln₃Al₅O₁₂:Ce and YAG:Ce³⁺.

7. Illumination system according to claim 1, wherein the radiation source is selected from the light emitting diodes having an emission with a peak emission wavelength in the UV range of 200 to 400 nm and wherein the luminescent material comprises a europium(II)-activated earth alkaline lithium orthosilicate of general formula (Sr_{1-x-y-z}CaₓBa_{y})Li₂SiO₄:Eu_{z} wherein 0≦x≦1; 0≦y≦1; 0.001≦z≦0.3.

8. Illumination system according to claim 1, wherein the radiation source is selected from the light emitting diodes having an emission with a peak emission wavelength in the UV-range of 200 to 400 nm and wherein the luminescent material comprises a europium(II)-activated earth alkaline lithium orthosilicate of general formula (Sr_{1-x-y-z}CaₓBa_{y})Li₂SiO₄:Eu_{z} wherein 0≦x≦1; 0≦y≦1; 0.001≦z≦0.3 and a second phosphor.

9. Illumination system according to claim 8, wherein the second phosphor is a blue phosphor selected from the group of BaMgAlₗₒ0₁₇:Eu, Ba₅SiO₄(Cl,Br)₆:Eu, CaLn₂S₄:Ce, (Sr,Ba,Ca)₅(PO₄)₃Cl:Eu and LaSi₃N₅:Ce.

10. Illumination system according to claim 8, wherein the second phosphor is a red phosphor selected from the group Ca₁₋ₓSrₓ) S:Eu, wherein 0≦x≦1 and (Sr_{1-x-y}BaₓCa_{y})_{2-z}Si₅₋ₐAlₐN₈₋ₐOₐ:Eu_{z} wherein 0≦a≦5.0; 0<x≦1, 0≦y≦1 and 0<z≦1.

11. Illumination system according to claim 8, wherein the second phosphor is a yellow to green phosphor selected from the group comprising (Ba₁₋ₓSrₓ)₂SiO₄:Eu, wherein 0≦x≦1, SrGa₂S₄:Eu, SrSi₂N₂O₂:Eu, Ln₃Al₅O₁₂:Ce and YAG:Ce³⁺.

12. Phosphor capable of absorbing a part of light emitted by the radiation source and emitting light of wavelength different from that of the absorbed light; wherein said phosphor is a europium(II)-activated earth alkaline lithium orthosilicate of general formula (Sr_{1-x-y-z}CaₓBa_{y})Li₂SiO₄:Eu_{z} wherein 0≦x≦1; 0≦y≦1; 0.001≦z≦0.3.

13. Phosphor according to claim 12, wherein said phosphor additionally comprises a co-activator.

14. Phosphor according to claim 12, wherein the phosphor has a coating selected from the group of fluorides and orthophosphates of the elements aluminum, scandium, yttrium, lanthanum gadolinium and lutetium, the oxides of aluminum, yttrium and lanthanum and the nitride of aluminum.
